(19) United States
(12) Patent Application Publication
(10) Pub. No.: US 2025/0212421 A1
(43) Pub. Date: Jun. 26, 2025

(54) MAGNETIC MEMORY DEVICE AND METHOD OF FABRICATING THE SAME

(71) Applicant: SAMSUNG ELECTRONICS CO., LTD., Suwon-si (KR)

(72) Inventors: Hyukjun KWON, Suwon-si (KR); Youngkeol KIM, Suwon-si (KR); Junghoon BAK, Suwon-si (KR); Geonhee BAE, Suwon-si (KR)

(73) Assignee: SAMSUNG ELECTRONICS CO., LTD., Suwon-si (KR)

(21) Appl. No.: 18/957,137

(22) Filed: Nov. 22, 2024

(30) Foreign Application Priority Data
Dec. 21, 2023 (KR) 10-2023-0187957

(51) Int. Cl. H10B 61/00

(52) U.S. Cl. CPC H10B 61/10

(57) ABSTRACT

A magnetic memory device includes: a substrate; a lower dielectric layer on the substrate; a plurality of lower electrode contacts in the lower dielectric layer, the plurality of lower electrode contacts being spaced apart from each other in a first direction parallel to a top surface of the substrate; a plurality of data storage patterns respectively on the plurality of lower electrode contacts, the plurality of data storage patterns being spaced apart from each other in the first direction; and a plurality of dielectric patterns on the lower dielectric layer between the plurality of data storage patterns, wherein the plurality of dielectric patterns include a metal element that is same or substantially same as that of the plurality of data storage patterns.

### CROSS-REFERENCE TO RELATED APPLICATION

This application is based on and claims priority under 35 U.S.C § 119 to Korean Patent Application No. 10-2023-0187957 filed on Dec. 21, 2023 in the Korean Intellectual Property Office, the disclosure of which is hereby incorporated by reference in its entirety.

### BACKGROUND

### 1. Field

The disclosure relates to a magnetic memory device, and, more particularly, to a magnetic memory device including a magnetic tunnel junction.

### 2. Detailed Description of Related Art

As electronic products trend toward high speed and/or low power consumption, high speed and low operating voltages are increasingly required for semiconductor memory devices incorporated in the electronic products. In order to meet these requirements, magnetic memory devices have been developed as semiconductor memory devices. Because the magnetic memory devices operate at high speeds and have nonvolatile characteristics, the magnetic memory devices have attracted considerable attention as the next-generation semiconductor memory devices.

In general, the magnetic memory device may include a magnetic tunnel junction (in short, MTJ). The magnetic tunnel junction may include two magnetic structures and a dielectric layer interposed therebetween. The resistance of the magnetic tunnel junction varies depending on magnetization directions of the two magnetic structures. For example, the magnetic tunnel junction has high resistance when the magnetization directions of the two magnetic structures are anti-parallel. In contrast, the magnetic tunnel junction has low resistance when the magnetization directions of the two magnetic structures are parallel. The magnetic memory device may write and read data using the resistance difference between the high and low resistances of the magnetic tunnel junction. In the electronic industry, there is an increasing demand for high integration and/or low power consumption of the magnetic memory devices. Accordingly, many studies have been conducted to meet the demand, but have not fully met the demand.

### SUMMARY

Provided are a magnetic memory device with improved electrical properties and a method of fabricating the same magnetic memory device.

According to an aspect of the disclosure, a magnetic memory device includes: a substrate; a lower dielectric layer on the substrate; a plurality of lower electrode contacts in the lower dielectric layer, the plurality of lower electrode contacts being spaced apart from each other in a first direction parallel to a top surface of the substrate; a plurality of data storage patterns respectively on the plurality of lower electrode contacts, the plurality of data storage patterns being spaced apart from each other in the first direction; and a plurality of dielectric patterns on the lower dielectric layer between the plurality of data storage patterns, wherein the plurality of dielectric patterns include a metal element that is same or substantially same as that of the plurality of data storage patterns.

According to an aspect of the disclosure, a magnetic memory device includes: a lower dielectric layer on a substrate; a plurality of data storage patterns that are horizontally spaced apart from each other on the lower dielectric layer; a plurality of dielectric patterns on the lower dielectric layer between the plurality of data storage patterns; and a capping dielectric layer that covers at least one lateral surface of at least one data storage pattern in the plurality of data storage patterns, wherein a top surface of the lower dielectric layer is recessed inwardly to one of the plurality of dielectric patterns between the plurality of data storage patterns, wherein the capping dielectric layer extends from the at least one lateral surface of the at least one data storage pattern onto the top surface of the lower dielectric layer, and wherein the plurality of dielectric patterns are between the capping dielectric layer and the top surface of the lower dielectric layer, and include a metal element that is the same or substantially same as that of the plurality of data storage patterns.

According to an aspect of the disclosure, a magnetic memory device includes: a lower dielectric layer on a substrate; a plurality of data storage patterns on the lower dielectric layer and spaced apart from each other in a first direction and a second direction that are parallel to a top surface of the substrate and intersecting each other; a plurality of lower electrode contacts between the substrate and the plurality of data storage patterns, the plurality of lower electrode contacts being in the lower dielectric layer and respectively connected to the plurality of data storage patterns; a capping dielectric layer that covers at least one lateral surface of at least one data storage pattern in the plurality of data storage patterns; a plurality of cell conductive lines that extend in the second direction and are spaced apart from each other in the first direction, wherein the plurality of cell conductive lines are respectively connected to the plurality of data storage patterns, and wherein the plurality of data storage patterns are spaced apart from each other in the second direction; and a plurality of dielectric patterns on the lower dielectric layer and between the plurality of data storage patterns, wherein the plurality of dielectric patterns include metal oxide, and wherein the capping dielectric layer covers at least one top surface of at least one dielectric pattern in the plurality of dielectric patterns.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a circuit diagram showing a unit memory cell of a magnetic memory device according to some embodiments of the disclosure;

FIG. 2 illustrates a plan view showing a magnetic memory device according to some embodiments of the disclosure;

FIG. 3 illustrates a cross-sectional view taken along line I-I′ of FIG. 2, showing a magnetic memory device according to some embodiments of the disclosure;

FIG. 4 illustrates an enlarged view of section A of FIG. 3, partially showing a magnetic memory device according to some embodiments of the disclosure;

FIGS. 5A and 5B illustrate cross-sectional views showing examples of a magnetic tunnel junction pattern in a magnetic memory device according to some embodiments of the disclosure;

FIGS. 6 to 11 illustrate cross-sectional views taken along line I-I′ of FIG. 2, showing a method of fabricating a magnetic memory device according to some embodiments of the disclosure;

FIG. 12 illustrates a cross-sectional view taken along line I-I′ of FIG. 2, showing a magnetic memory device according to some embodiments of the disclosure; and

FIGS. 13 to 15 illustrate cross-sectional views taken along line I-I′ of FIG. 2, showing a method of fabricating a magnetic memory device according to some embodiments of the disclosure.

### DETAILED DESCRIPTION

The following will now describe in detail some embodiments of the present inventive concepts with reference to the accompanying drawings. The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

The terms “include” and “comprise”, and the derivatives thereof refer to inclusion without limitation. The term “or” is an inclusive term meaning “and/or”. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

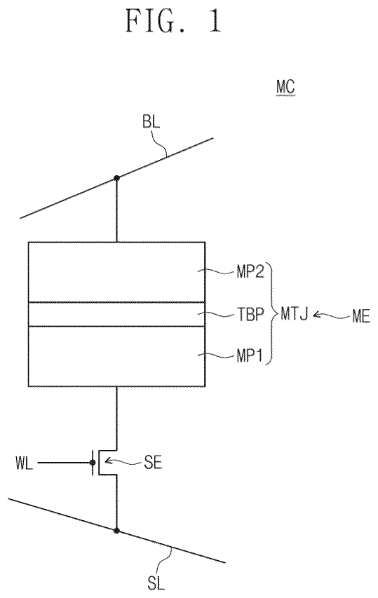

FIG. 1 illustrates a circuit diagram showing a unit memory cell of a magnetic memory device according to some embodiments of the present inventive concepts.

Referring to FIG. 1, a unit memory cell MC may include a memory element ME and a selection element SE. The memory element ME and the selection element SE may be electrically connected in series to each other. The memory element ME may be connected between a bit line BL and the selection element SE. The selection element SE may be connected between the memory element ME and a source line SL, and may be controlled by a word line WL. The selection element SE may include, for example, a bipolar transistor or a metal oxide semiconductor (MOS) field effect transistor.

The memory element ME may include a magnetic tunnel junction pattern MTJ including magnetic patterns MP1 and MP2 that are spaced apart from each other and also including a tunnel barrier pattern TBP between the magnetic patterns MP1 and MP2. One of the magnetic patterns MP1 and MP2 may be a reference magnetic pattern having a magnetization direction that is fixed regardless of an external magnetic field under a normal use environment. The other of the magnetic patterns MP1 and MP2 may be a free magnetic pattern whose magnetization direction is changed due to an external magnetic field between two stable magnetization directions. The magnetic tunnel junction pattern MTJ may have an electrical resistance whose value is much greater in a case that the magnetization directions of the reference magnetic pattern and the free magnetic pattern are antiparallel to each other than in a case that the magnetization directions of the reference magnetic pattern and the free magnetic pattern are parallel to each other. For example, the electrical resistance of the magnetic tunnel junction pattern MTJ may be controlled by changing the magnetization direction of the free magnetic pattern. The memory element ME may use the difference in electrical resistance dependent on the magnetization directions of the reference magnetic pattern and the free magnetic pattern, which mechanism may cause the unit memory cell MC to store data therein.

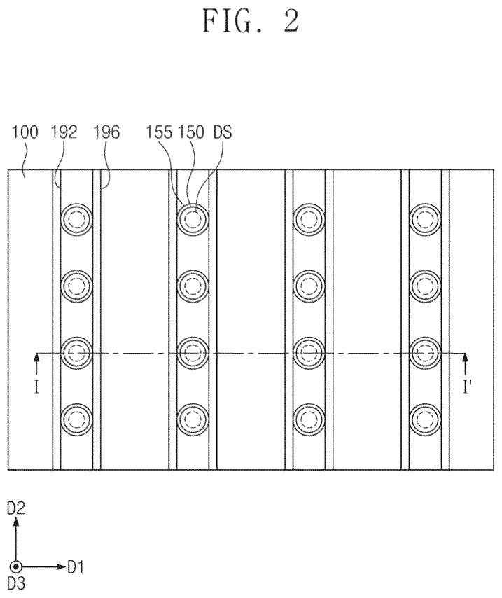

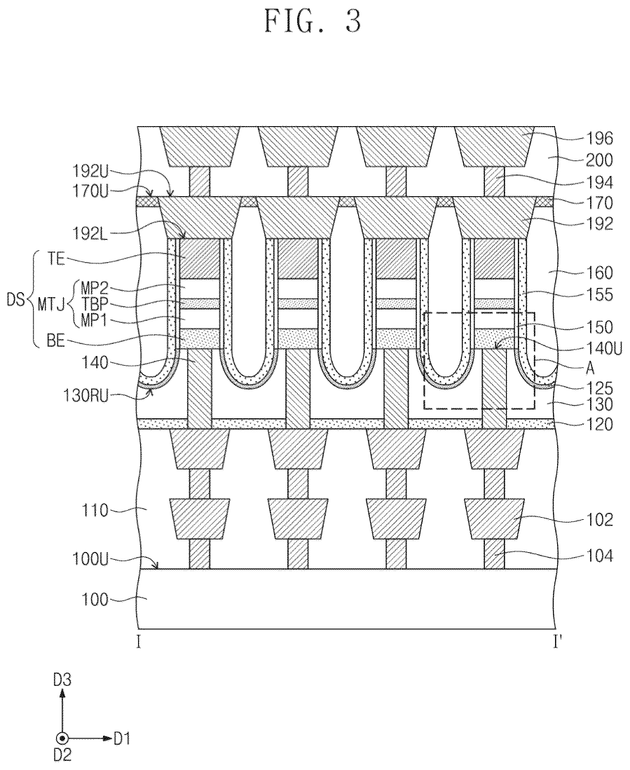

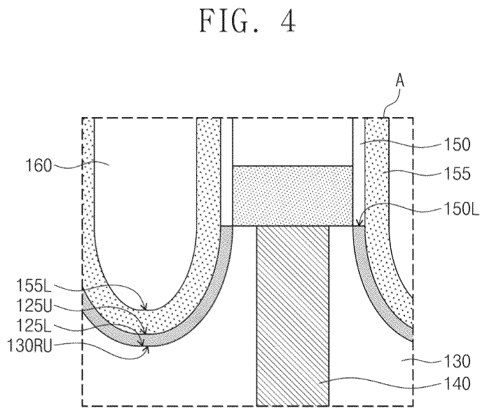

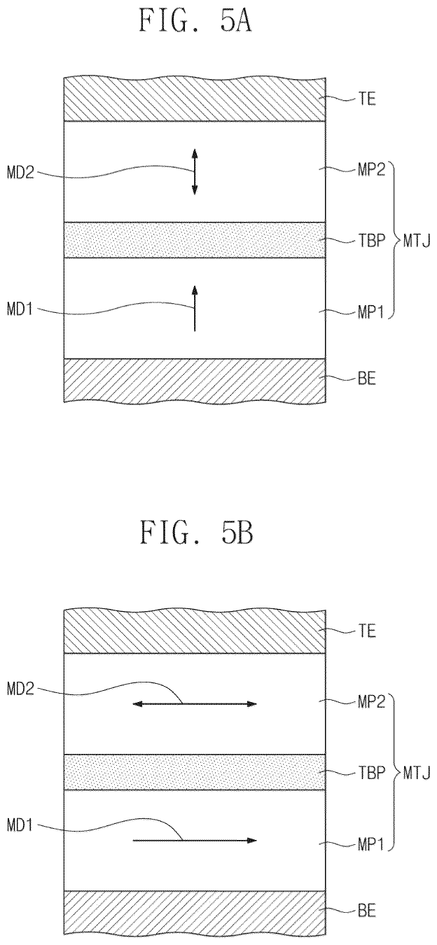

FIG. 2 illustrates a plan view showing a magnetic memory device according to some embodiments of the disclosure. FIG. 3 illustrates a cross-sectional view taken along line I-I′ of FIG. 2, showing a magnetic memory device according to some embodiments of the disclosure. FIG. 4 illustrates an enlarged view of section A depicted in FIG. 3, partially showing a magnetic memory device according to some embodiments of the disclosure. FIGS. 5A and 5B illustrate cross-sectional views showing examples of a magnetic tunnel junction pattern in a magnetic memory device according to some embodiments of the disclosure.

Referring to FIGS. 2 to 4, a wiring structure (wiring lines 102 and wiring contacts 104) may be disposed on a substrate 100. The wiring structure (the wiring lines 102 and the wiring contacts 104) may include the wiring lines 102 vertically spaced apart from the substrate 100 and the wiring contacts 104 connected to the wiring lines 102. The substrate 100 may be a semiconductor substrate including silicon (Si), silicon-on-insulator (SOI), silicon-germanium (SiGe), germanium (Ge), or gallium-arsenic (GaAs).

The wiring lines 102 may be spaced apart from a top surface 100U of the substrate 100 along a direction perpendicular to the top surface 100U of the substrate 100. The wiring contacts 104 may be disposed between the substrate 100 and the wiring lines 102. Each of the wiring lines 102 may be electrically connected to the substrate 100 through a corresponding one of the wiring contacts 104. The wiring lines 102 and the wiring contacts 104 may include metal (e.g., copper).

Selection elements (see SE of FIG. 1) may be disposed on the substrate 100. The selection elements may be, for example, field effect transistors. Each of the wiring lines 102 may be electrically connected through a corresponding one of the wiring contacts 104 to one terminal (e.g., a source terminal, a drain terminal, or a gate terminal) of a corresponding one of the selection elements.

A wiring dielectric layer 110 may be disposed on the substrate 100 to cover the wiring structure 102 and 104. The wiring dielectric layer 110 may expose top surfaces of uppermost ones of the wiring lines 102. For example, the wiring dielectric layer 110 may have a top surface substantially coplanar with those of the uppermost wiring lines 102. The wiring dielectric layer 110 may include, for example, one or more of silicon oxide, silicon nitride, and silicon oxynitride.

A first interlayer dielectric layer 120 may be disposed on the wiring dielectric layer 110, and may cover the exposed top surfaces of the uppermost wiring lines 102. The first interlayer dielectric layer 120 may include, for example, one or more of silicon oxide, silicon nitride, and silicon oxynitride.

A lower dielectric layer 130 may be disposed on the first interlayer dielectric layer 120. The lower dielectric layer 130 may include, for example, one or more of silicon oxide, silicon nitride, and silicon oxynitride.

Data storage patterns DS may be disposed on the lower dielectric layer 130. The data storage patterns DS may be horizontally spaced apart from each other, and for example, may be spaced apart from each other in a first direction D1 and a second direction D2 that intersect each other and are parallel to the top surface 100U of the substrate 100. The lower dielectric layer 130 may have a top surface 130RU that is recessed inwardly to the lower dielectric layer 130 between the data storage patterns DS. In this description, the term “height” may indicate a distance measured from the top surface 100U of the substrate 100 in a third direction D3 perpendicular to the top surface 100U of the substrate 100.

Lower electrode contacts 140 may be disposed on the lower dielectric layer 130, and may be spaced apart from each other in the first direction D1 and the second direction D2. The lower electrode contacts 140 may be correspondingly disposed below the data storage patterns DS, and may be electrically connected to correspondingly data storage patterns DS. Each of the lower electrode contacts 140 may penetrate the first interlayer dielectric layer 120 and the lower dielectric layer 130, and may be connected to a corresponding one of the uppermost wiring lines 102. Each of the data storage patterns DS may be electrically connected to one terminal (e.g., a drain terminal) of a corresponding selection element through a corresponding lower electrode contact 140 and a corresponding uppermost wiring line 102.

The lower electrode contacts 140 may have their top surfaces 140U located at a height higher than that of the recessed top surface 130RU of the lower dielectric layer 130. The lower electrode contacts 140 may include at least one selected from doped semiconductor materials (e.g., doped silicon), metals (e.g., one or more of tungsten, titanium, and tantalum), metal-semiconductor compounds (e.g., metal silicide), and conductive metal nitrides (e.g., one or more of titanium nitride, tantalum nitride, and tungsten nitride).

Each of the data storage patterns DS may include a bottom electrode BE, a magnetic tunnel junction pattern MTJ, and a top electrode TE that are sequentially stacked in the third direction D3 on the lower dielectric layer 130. The magnetic tunnel junction pattern MTJ may be disposed between the bottom electrode BE and the top electrode TE. The lower electrode contacts 140 may be correspondingly connected to the bottom electrodes BE of the data storage patterns DS. The magnetic tunnel junction pattern MTJ may include a first magnetic pattern MP1, a second magnetic pattern MP2, and a tunnel barrier pattern TBP between the first magnetic pattern MP1 and the second magnetic pattern MP2. The first magnetic pattern MP1 may be disposed between the bottom electrode BE and the tunnel barrier pattern TBP, and the second magnetic pattern MP2 may be disposed between the top electrode TE and the tunnel barrier pattern TBP. The bottom electrode BE may include, for example, conductive metal nitride (e.g., titanium nitride or tantalum nitride). The top electrode TE may include at least one selected from metal (e.g., Ta, W, Ru, or Ir) and conductive metal nitride (e.g., TiN).

Referring to FIG. 5A, for example, magnetization directions MD1 and MD2 of the first and second magnetic patterns MP1 and MP2 may be perpendicular to an interface between the tunnel barrier pattern TBP and the second magnetic pattern MP2. In this case, each of the first and second magnetic patterns MP1 and MP2 may include at least one selected from an intrinsic perpendicular magnetic material and an extrinsic perpendicular magnetic material. The intrinsic perpendicular magnetic material may include a material having perpendicular magnetization properties found even in the absence of an external factor. The intrinsic perpendicular magnetic material may include at least one selected from a perpendicular magnetic material (e.g., CoFeTb, CoFeGd, CoFeDy), a perpendicular magnetic material having an L1₀ structure, CoPt of a hexagonal close-packed (HCP) lattice structure, and a perpendicular magnetic structure. The perpendicular magnetic material having the L1₀ structure may include at least one selected from FePt of the L1₀ structure, FePd of the L1₀ structure, CoPd of the L1₀ structure, and CoPt of the L1₀ structure. The perpendicular magnetic structure may include magnetic layers and non-magnetic layers that are alternately and repeatedly stacked. For example, the perpendicular magnetic structure may include at least one selected from (Co/Pt)n, (CoFe/Pt)n, (CoFe/Pd)n, (Co/Pd)n, (Co/Ni)n, (CoNi/Pt)n, (CoCr/Pt)n, and (CoCr/Pd)n (where, n is the number of stacked layers). The extrinsic perpendicular magnetic material may include a material having intrinsic horizontal magnetization properties or perpendicular magnetization properties caused by an external factor. For example, the extrinsic perpendicular magnetic material may have perpendicular magnetization properties due to magnetic anisotropy induced by junction between the tunnel barrier pattern TBP and the first magnetic pattern MP1 (or the second magnetic pattern MP2). The extrinsic perpendicular magnetic material may include, for example, CoFeB.

Referring to FIG. 5B, for example, the magnetization directions MD1 and MD2 of the first and second magnetic patterns MP1 and MP2 may be parallel to the interface between the tunnel barrier pattern TBP and the second magnetic pattern MP2. In this case, each of the first and second magnetic patterns MP1 and MP2 may include a ferromagnetic material. The first magnetic pattern MP1 may further include an antiferromagnetic material for fixing a magnetization direction of the ferromagnetic material in the first magnetic pattern MP1.

Each of the first and second magnetic patterns MP1 and MP2 may include a Heusler alloy including Co. The tunnel barrier pattern TBP may include at least one selected from a magnesium (Mg) oxide layer, a titanium (Ti) oxide layer, an aluminum (Al) oxide layer, a magnesium-zinc (MgZn) oxide layer, and a magnesium-boron (MgB) oxide layer.

Referring back to FIGS. 2 to 4, capping patterns 150 may be disposed on the lower dielectric layer 130, and may be spaced apart from each other in the first direction D1 and the second direction D2. The capping patterns 150 may conformally cover lateral surfaces of corresponding data storage patterns DS. Each of the capping patterns 150 may conformally cover lateral surfaces of the bottom electrode BE, the magnetic tunnel junction pattern MTJ, and the top electrode TE. When viewed in plan, each of the capping patterns 150 may surround the lateral surfaces of the bottom electrode BE, the magnetic tunnel junction pattern MTJ, and the top electrode TE. The capping patterns 150 may include nitride (e.g., silicon nitride).

Dielectric patterns 125 may be disposed on the lower dielectric layer 130, and may be spaced apart from each other horizontally (e.g., in the first direction D1 and the second direction D2). The dielectric pattern 125 may be disposed between the data storage patterns DS, and may be placed on the recessed top surface 130RU of the lower dielectric layer 130. Each of the dielectric patterns 125 may have a lowermost surface 125L located at a height lower than that of a lowermost surface 150L of each of the capping patterns 150. The lowermost surface 125L of each of the dielectric patterns 125 may be located at a height lower than that of the top surfaces 140U of the lower electrode contacts 140. The dielectric patterns 125 may include a metal element that may be same or substantially same as that of the data storage patterns DS. The dielectric patterns 125 may include metal oxide, and for example, oxides of metal elements in the data storage patterns DS.

According to the disclosure, the dielectric pattern 125 may be formed between the data storage patterns DS. This configuration may block a leakage current between the data storage patterns DS and may prevent an electrical short. It may therefore be possible to provide a magnetic memory device with improved electrical properties.

A capping dielectric layer 155 may be disposed on the lower dielectric layer 130, and may extend along the recessed top surface 130RU of the lower dielectric layer 130. The capping dielectric layer 155 may cover the recessed top surface 130RU of the lower dielectric layer 130, and may conformally cover a top surface 125U of the dielectric pattern 125. The capping dielectric layer 155 may have a lowermost surface 155L located at a height lower than that of the lowermost surface 150L of each of the capping patterns 150. The dielectric pattern 125 may be interposed between the capping dielectric layer 155 and the lower dielectric layer 130. Each of the capping patterns 150 may be interposed between the capping dielectric layer 155 and the lateral surface of the data storage pattern DS. The capping dielectric layer 155 may cover the lateral surface of the data storage pattern DS and a lateral surface of the capping pattern 150. The lowermost surface 155L of the capping dielectric layer 155 may be located at a height lower than that of the top surface 140U of the lower electrode contact 140. The capping dielectric layer 155 may include a material, such as nitride (e.g., silicon nitride), that is the same or substantially same as that of the capping pattern 150.

A cell dielectric layer 160 may be disposed on the lower dielectric layer 130, and may cover the data storage patterns DS. The cell dielectric layer 160 may fill a space between the data storage patterns DS. The capping dielectric layer 155 may be interposed between the cell dielectric layer 160 and the lateral surface of the capping pattern 150. The cell dielectric layer 160 may include, for example, one or more of silicon oxide, silicon nitride, and silicon oxynitride. For example, the cell dielectric layer 160 may include tetraethylorthosilicate (TEOS) oxide.

A second interlayer dielectric layer 170 may be disposed on the cell dielectric layer 160. The second interlayer dielectric layer 170 may include a material different from that of the cell dielectric layer 160. The second interlayer dielectric layer 170 may include silicon nitride (e.g., SiCN).

First cell conductive lines 192 may be disposed on the data storage patterns DS. The first cell conductive lines 192 may extend in the second direction D2 and may be spaced apart from each other in the first direction D1. Each of the first cell conductive lines 192 may have a linear shape that extends in the second direction D2. Each of the first cell conductive lines 192 may be electrically connected to corresponding data storage patterns DS that are spaced apart from each other in the second direction D2. Each of the first cell conductive lines 192 may penetrate the second interlayer dielectric layer 170, and may also penetrate an upper portion of the cell dielectric layer 160 to come into connection with the corresponding data storage patterns DS that are spaced apart from each other in the second direction D2.

A bottom surface 192L of each of the first cell conductive lines 192 may be in contact with the corresponding data storage patterns DS that are spaced apart from each other in the second direction D2, and may also be in contact with the top electrode TE of each of the corresponding data storage patterns DS that are spaced apart from each other in the second direction D2. The first cell conductive lines 192 may include a conductive material, such as metal (e.g., copper).

An upper dielectric layer 200 may cover a top surface 170U of the second interlayer dielectric layer 170 and top surfaces 192U of the first cell conductive lines 192. The upper dielectric layer 200 may include, for example, one or more of silicon oxide, silicon nitride, and silicon oxynitride.

Second cell conductive lines 196 may be disposed in the upper dielectric layer 200. The second cell conductive lines 196 may overlap vertically (e.g., in the third direction D3) with the first cell conductive lines 192.

First conductive contacts 194 may be disposed in the upper dielectric layer 200, and may be placed between the first cell conductive lines 192 and the second cell conductive lines 196. A bit line (see BL of FIG. 1) may be constituted by each of the first cell conductive lines 192, a corresponding one of the first conductive contacts 194, and each of the second cell conductive lines 196. The first conductive contacts 194 and the second cell conductive lines 196 may include a conductive material, such as metal (e.g., copper).

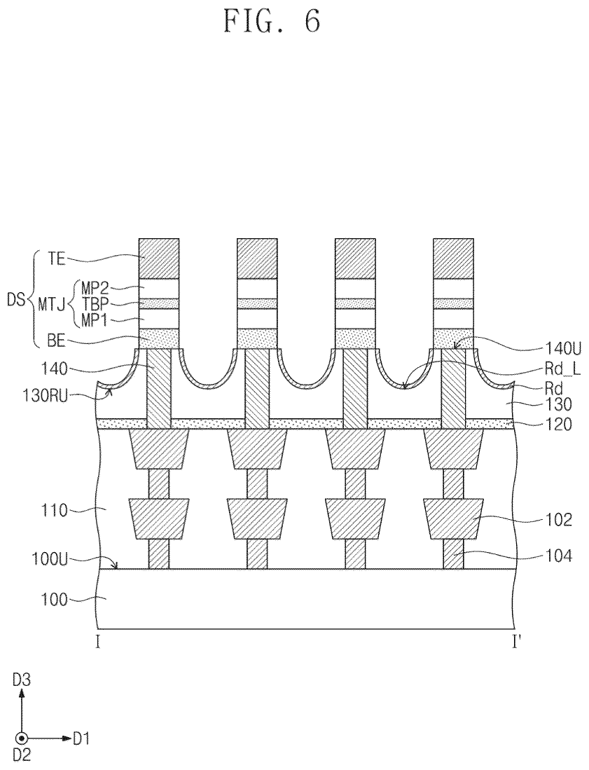

FIGS. 6 to 11 illustrate cross-sectional views taken along line I-I′ of FIG. 2, showing a method of fabricating a magnetic memory device according to some embodiments of the disclosure. For brevity of description, omission will be made to avoid an explanation of that discussed with reference to FIGS. 1 to 4, 5A, and 5B.

Referring to FIGS. 2 and 6, a substrate 100 may be provided which extends in the first direction D1 and the second direction D2. Selection elements (see SE of FIG. 1) may be formed on the substrate 100, and a wiring structure 102 and 104 may be formed on the selection elements. The wiring structure 102 and 104 may include wiring lines 102 that are spaced vertically (e.g., in the third direction D3) apart from the substrate 100, and may also include wiring contacts 104 connected to the wiring lines 102. Each of the wiring lines 102 may be electrically connected through a corresponding one of the wiring contacts 104 to one terminal (e.g., a source terminal, a drain terminal, or a gate terminal) of a corresponding one of the selection elements.

A wiring dielectric layer 110 may be formed on the substrate 100, and may cover the wiring structure 102 and 104. The wiring dielectric layer 110 may expose top surfaces of uppermost ones of the wiring lines 102.

A first interlayer dielectric layer 120 may be formed on the wiring dielectric layer 110, and may cover the exposed top surfaces of the uppermost wiring lines 102. The first interlayer dielectric layer 120 may be formed on the wiring dielectric layer 110 on the substrate 100. A lower dielectric layer 130 may be formed on the first interlayer dielectric layer 120.

Lower electrode contacts 140 may be formed in the lower dielectric layer 130. Each of the lower electrode contacts 140 may penetrate the first interlayer dielectric layer 120 and the lower dielectric layer 130, and may be electrically connected to one of the uppermost wiring lines 102. The formation of the lower electrode contacts 140 may include, for example, forming lower contact holes that penetrate the first interlayer dielectric layer 120 and the lower dielectric layer 130, forming on the lower dielectric layer 130 a lower contact layer that fills the lower contact holes, and planarizing the lower contact layer until a top surface of the lower dielectric layer 130 is exposed. In the planarization process, the lower electrode contacts 140 may be locally formed in corresponding lower contact holes.

Data storage patterns DS may be formed on the lower dielectric layer 130. The lower electrode contacts 140 may be correspondingly disposed below and electrically connected to the data storage patterns DS.

Each of the data storage patterns DS may include a bottom electrode BE, a magnetic tunnel junction pattern MTJ, and a top electrode TE that are sequentially stacked on the lower dielectric layer 130. The magnetic tunnel junction pattern MTJ may include a first magnetic pattern MP1, a second magnetic pattern MP2, and a tunnel barrier pattern TBP between the first magnetic pattern MP1 and the second magnetic pattern MP2. The first magnetic pattern MP1 may be disposed between the bottom electrode BE and the tunnel barrier pattern TBP, and the second magnetic pattern MP2 may be disposed between the top electrode TE and the tunnel barrier pattern TBP. The formation of the data storage patterns DS may include, for example, sequentially forming a lower electrode layer and a magnetic tunnel junction layer on the lower dielectric layer 130, forming a conductive mask pattern on the magnetic tunnel junction layer, and using the conductive mask pattern as an etch mask to sequentially etch the magnetic tunnel junction layer and the lower electrode layer. The magnetic tunnel junction layer may include a first magnetic layer, a tunnel barrier layer, and a second magnetic layer that are sequentially stacked on the lower electrode layer. The magnetic tunnel junction layer and the lower electrode layer may be formed by, for example, a sputtering process, a chemical vapor deposition process, or an atomic layer deposition process.

The magnetic tunnel junction layer and the lower electrode layer may be etched to respectively form the magnetic tunnel junction pattern MTJ and the bottom electrode BE. The etching of the magnetic tunnel junction layer may include using the conductive mask pattern as an etch mask to sequentially etch the second magnetic layer, the tunnel barrier layer, and the first magnetic layer. The second magnetic layer, the tunnel barrier layer, and the first magnetic layer may be etched to form the second magnetic pattern MP2, the tunnel barrier pattern TBP, and the first magnetic pattern MP1. The conductive mask pattern may remain on the magnetic tunnel junction pattern MTJ after the magnetic tunnel junction layer and the lower electrode layer are etched, and the remainder of the conductive mask pattern may be defined as the top electrode TE.

An ion beam etching process that uses an ion beam may be used to perform an etching process for etching the magnetic tunnel junction layer and the lower electrode layer. The ion beam may include inert ions. The etching process may recess an upper portion of the lower dielectric layer 130 between the data storage patterns DS. The lower dielectric layer 130 may have a top surface 130RU that is recessed inwardly to the lower dielectric layer 130. The recessed top surface 130RU of the lower dielectric layer 130 may be located at a height lower than that of top surfaces 140U of the lower electrode contacts 140.

In the etching process that etches the magnetic tunnel junction layer and the lower electrode layer, redeposited material patterns Rd may be formed on the recessed top surface 130RU of the lower dielectric layer 130. Each of the redeposited material patterns Rd may be disposed between the data storage patterns DS, and may have a lowermost surface Rd_L located at a height lower than that of the top surfaces 140U of the lower electrode contacts 140. The redeposited material patterns Rd may include, for example, a metal element that is the same or substantially same as that of the data storage patterns DS.

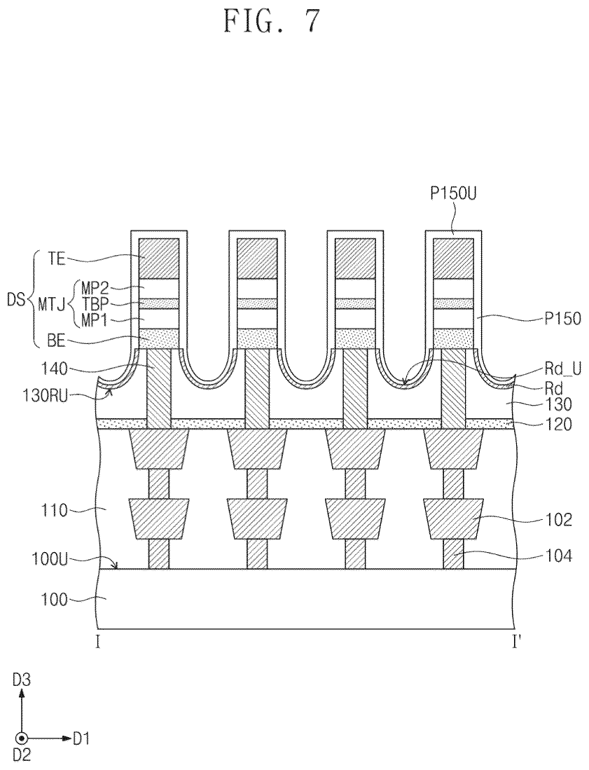

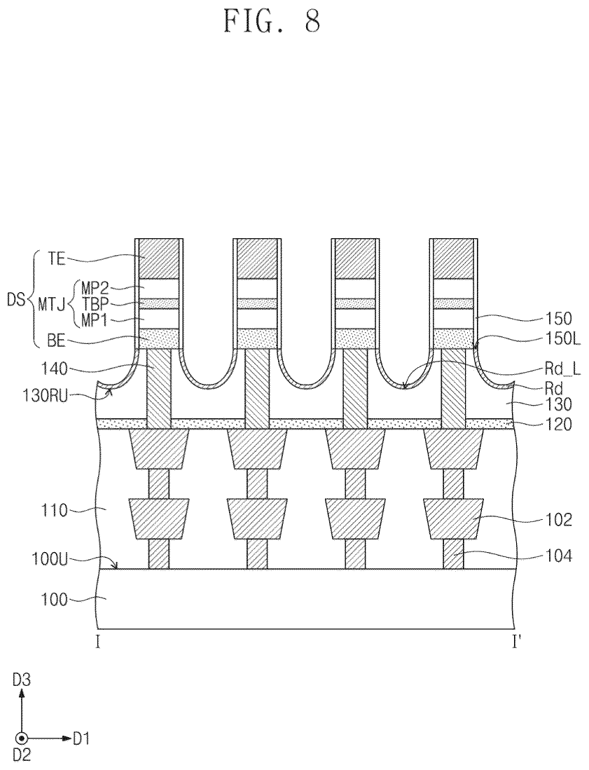

Referring to FIGS. 7 and 8, a preliminary capping pattern layer P150 may be formed on the lower dielectric layer 130, and may conformally cover a top surface and a lateral surface of each of the data storage patterns DS. The preliminary capping pattern layer P150 may conformally cover the recessed top surface 130RU of the lower dielectric layer 130, and may cover top surfaces Rd_U of the redeposited material patterns Rd. A portion of the preliminary capping pattern layer P150 may be removed which is formed on the recessed top surface 130RU of the lower dielectric layer 130, and this may expose the top surface Rd_U of the redeposited material pattern Rd between the data storage patterns DS. A first etching process may be performed to remove the portion of the preliminary capping pattern layer P150. For example, the first etching process may be an ion beam etching process, and the ion beam may include inert ions. The first etching process may expose the top surfaces Rd_U of the redeposited material patterns Rd. The first etching process may remove an upper portion P150U of the preliminary capping pattern layer P150 that covers the top surfaces of the data storage patterns DS, and may expose the top surfaces of the data storage patterns DS. The portion of the preliminary capping pattern layer P150 and the upper portion P150U of the preliminary capping pattern layer P150 may be etched to form capping patterns 150. The capping patterns 150 may cover the lateral surfaces of the data storage patterns DS, and may have their lowermost surfaces 150L located at a height higher than that of lowermost surfaces Rd_L of the redeposited material patterns Rd.

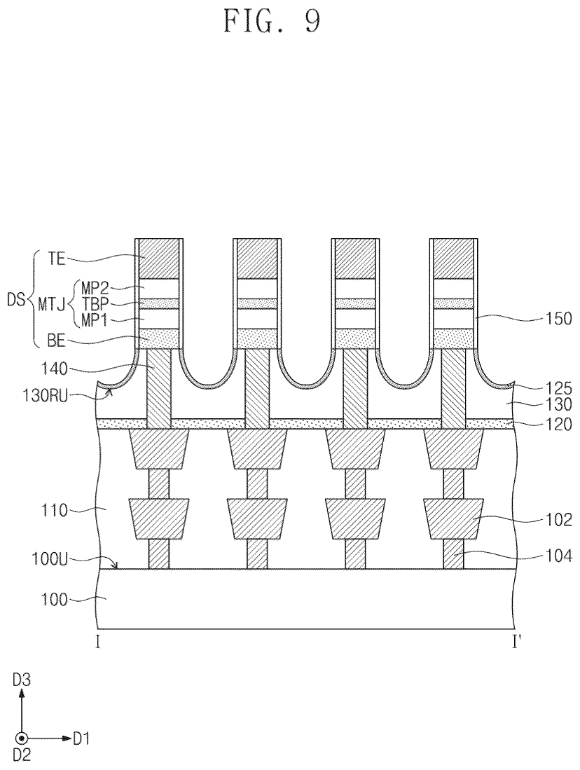

Referring to FIGS. 2 and 9, dielectric patterns 125 may be formed on the lower dielectric layer 130 and between the data storage patterns DS. The formation of the dielectric patterns 125 may include, for example, oxidizing the redeposited material patterns Rd. For example, an ion beam plasma process may be performed to oxidize the redeposited material patterns Rd.

In general, an etching process that etches the magnetic tunnel junction layer and the lower electrode layer may form the redeposited material patterns Rd between the data storage patterns DS. The redeposited material patterns Rd may have conductivity, and thus there may occur a short circuit in which the data storage patterns DS are electrically connected to each other. According to the disclosure, the redeposited material patterns Rd may be oxidized to form the dielectric patterns 125 between the data storage patterns DS. This configuration may block a leakage current between the data storage patterns DS and may prevent an electrical short. It may therefore be possible to provide a magnetic memory device with improved electrical properties.

In addition, according to the disclosure, after the first etching process is performed to etch the portion of the preliminary capping pattern layer P150 on the recessed top surface 130RU of the lower dielectric layer 130, no additional etching process may be required to remove the redeposited material patterns Rd. Thus, the lower dielectric layer 130 below the redeposited material patterns Rd may not be etched, and accordingly the lower dielectric layer 130 may be prevented from interface defects thereof. As a result, it may be possible to provide a magnetic memory device with enhanced interface properties and a method of fabricating a magnetic memory device whose process difficulty is improved.

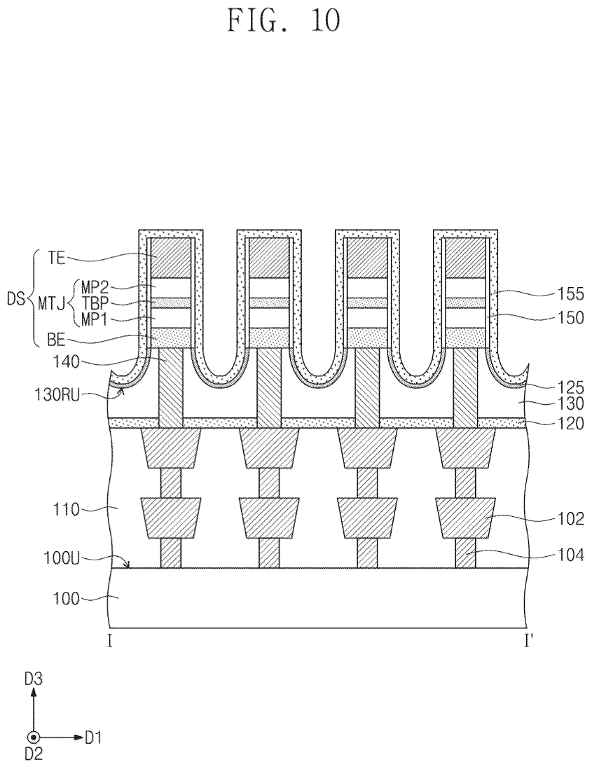

Referring to FIGS. 2 and 10, a capping dielectric layer 155 may be formed on the lower dielectric layer 130, while covering the recessed top surface 130RU of the lower dielectric layer 130. The capping dielectric layer 155 may cover top surfaces of the dielectric patterns 125, and may also cover a lateral surface and a top surface of each of the capping patterns 150. The capping dielectric layer 155 may cover the exposed top surfaces of the data storage patterns DS.

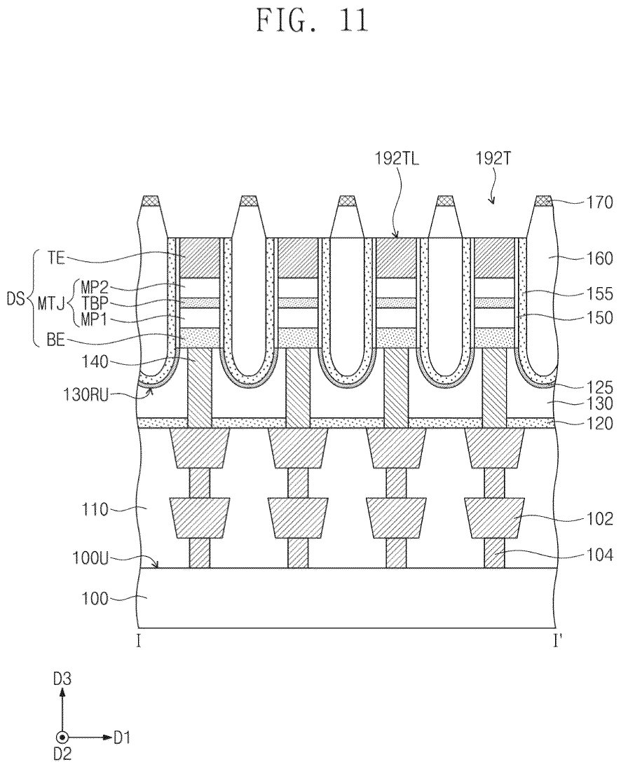

Referring to FIGS. 2 and 11, a cell dielectric layer 160 may be formed on the capping dielectric layer 155. The cell dielectric layer 160 may cover the data storage patterns DS, and may fill a space between the data storage patterns DS. The cell dielectric layer 160 may be formed by using, for example, high density plasma chemical vapor deposition (HDPCVD). A second interlayer dielectric layer 170 may be formed on the cell dielectric layer 160.

First cell trenches 192T may be formed penetrating the cell dielectric layer 160 and the second interlayer dielectric layer 170. The first cell trenches 192T may be spaced apart from each other in the first direction D1, while extending in the second direction D2. Each of the first cell trenches 192T may have a linear shape that extends in the second direction D2, and may expose corresponding data storage patterns DS that are spaced apart from each other in the second direction D2. A bottom surface 192TL of each of the first cell trenches 192T may expose the top electrode TE of each of the corresponding data storage patterns DS. A second etching process may form the first cell trenches 192T. The second etching process may include, for example, forming a mask pattern that defines regions where the first cell trenches 192T will be formed, and using the mask pattern as an etch mask to etch the second interlayer dielectric layer 170 and the cell dielectric layer 160.

Referring back to FIGS. 2 to 4, first cell conductive lines 192 may be correspondingly formed in the first cell trenches 192T. The formation of the first cell conductive lines 192 may include, for example, forming a first conductive layer that fills the first cell trenches 192T, and planarizing the first conductive layer until the top surface 170U of the second interlayer dielectric layer 170 is exposed. The planarization process may cause the first cell conductive lines 192 to have their top surfaces 192U located at the same height as that of the top surface 170U of the second interlayer dielectric layer 170.

An upper dielectric layer 200 may be formed on the second interlayer dielectric layer 170. The upper dielectric layer 200 may cover the top surface 170U of the second interlayer dielectric layer 170 and the top surfaces 192U of the first cell conductive lines 192.

Second cell conductive lines 196 and first conductive contacts 194 may be formed in the upper dielectric layer 200. The formation of the second cell conductive lines 196 and the first conductive contacts 194 may include, for example, forming second trenches that penetrate an upper portion of the upper dielectric layer 200, forming first holes that penetrate from bottom surfaces of the second cell trenches through a lower portion of the upper dielectric layer 200, forming on the upper dielectric layer 200 a second conductive layer that fills the second cell trenches and the first holes, and planarizing the second conductive layer until a top surface of the upper dielectric layer 200 is exposed.

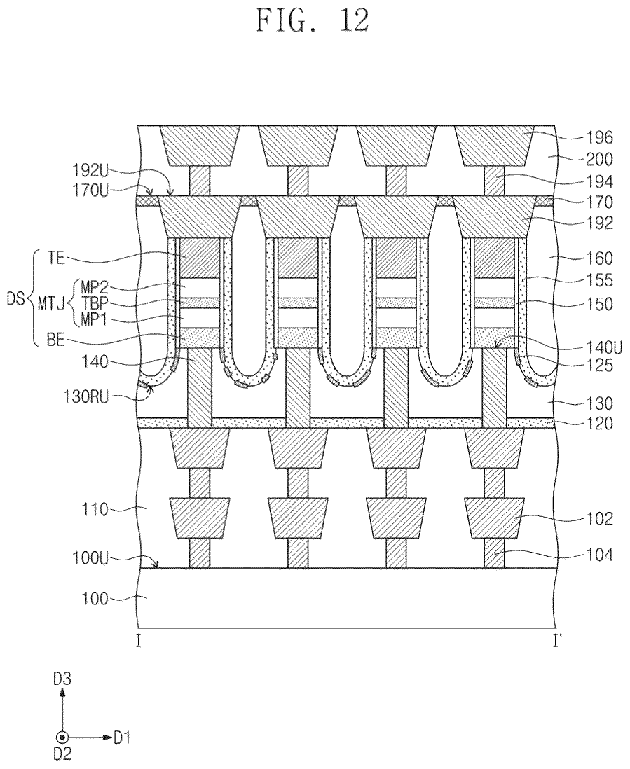

FIG. 12 illustrates a cross-sectional view taken along line I-I′ of FIG. 2, showing a magnetic memory device according to some embodiments of the disclosure. For brevity of description, omission will be made to avoid an explanation of that discussed with reference to FIGS. 1 to 4, 5A, and 5B.

Referring to FIG. 12, according to some embodiments of the disclosure, the dielectric patterns 125 may be spaced apart from each other along the recessed top surface 130RU of the lower dielectric layer 130. A lowermost one of the dielectric patterns 125 may be located at a height lower than that of the top surfaces 140U of the lower electrode contacts 140. The lowermost one of the dielectric patterns 125 may be located at a height lower than a lowermost surface of each of the capping patterns 150. The dielectric patterns 125 may include a metal element that is the same or substantially same as that of the data storage patterns DS. The dielectric patterns 125 may include metal oxide, and for example, oxides of metal elements in the data storage patterns DS.

The capping dielectric layer 155 may be disposed on the lower dielectric layer 130. The capping dielectric layer 155 may cover the top surface of each of the dielectric patterns 125, and may cover the recessed top surface 130RU of the lower dielectric layer 130. The capping dielectric layer 155 may be in contact with the recessed top surface 130RU of the lower dielectric layer 130 between the dielectric patterns 125.

According to the disclosure, the dielectric pattern 125 may be formed between the data storage patterns DS. This configuration may block a leakage current between the data storage patterns DS and may prevent an electrical short. It may therefore be possible to provide a magnetic memory device with improved electrical properties. Other structures may be substantially same as those discussed with reference to FIGS. 2 to 4, 5A, and 5B.

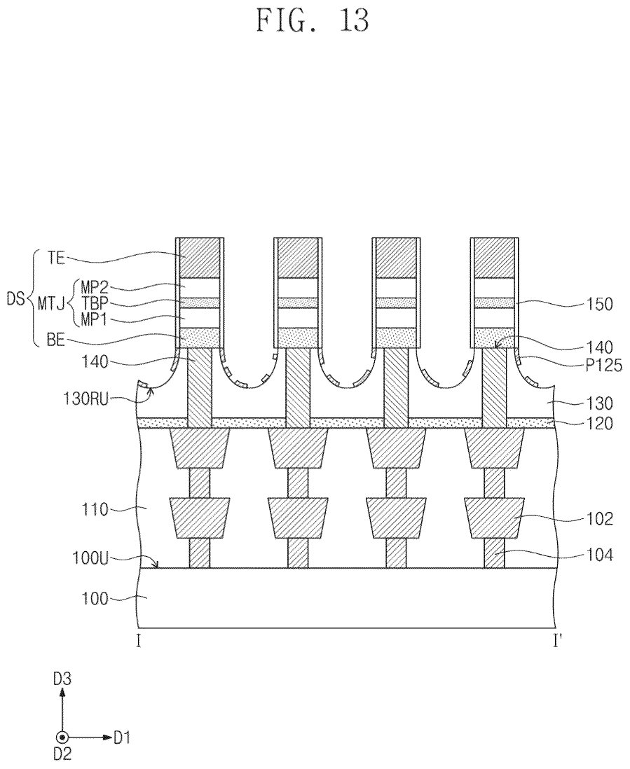

FIGS. 13 to 15 illustrate cross-sectional views taken along line I-I′ of FIG. 2, showing a method of fabricating a magnetic memory device according to some embodiments of the disclosure. For brevity of description, omission will be made to avoid an explanation of that discussed with reference to FIGS. 1 to 4, 5A, and 5B.

As discussed with reference to FIGS. 6 and 7, in the etching process that etches the magnetic tunnel junction layer and the lower electrode layer, redeposited material patterns Rd may be formed on the recessed top surface 130RU of the lower dielectric layer 130. A preliminary capping pattern layer P150 may be formed on the lower dielectric layer 130, and may conformally cover a top surface and a lateral surface of each of the data storage patterns DS. The preliminary capping pattern layer P150 may conformally cover the recessed top surface 130RU of the lower dielectric layer 130, and may cover top surfaces Rd_U of the redeposited material patterns Rd.

Referring to FIGS. 7 and 13, a portion of the preliminary capping pattern layer P150 may be removed which is formed on the recessed top surface 130RU of the lower dielectric layer 130, and this may expose the top surface Rd_U of the redeposited material pattern Rd between the data storage patterns DS. The removal of the portion of the preliminary capping pattern layer P150 may include, for example, performing a first etching process. For example, the first etching process may be an ion beam etching process, and the ion beam may include inert ions. The first etching process may remove an upper portion P150U of the preliminary capping pattern layer P150 that covers uppermost surfaces of the data storage patterns DS, and may expose the top surfaces of the data storage patterns DS.

According to some embodiments of the disclosure, the first etching process may partially remove the redeposited material patterns Rd, and this may form preliminary dielectric patterns P125. The preliminary dielectric patterns P125 may be spaced apart from each other along the recessed top surface 130RU of the lower dielectric layer 130, and may expose the recessed top surface 130RU of the lower dielectric layer 130.

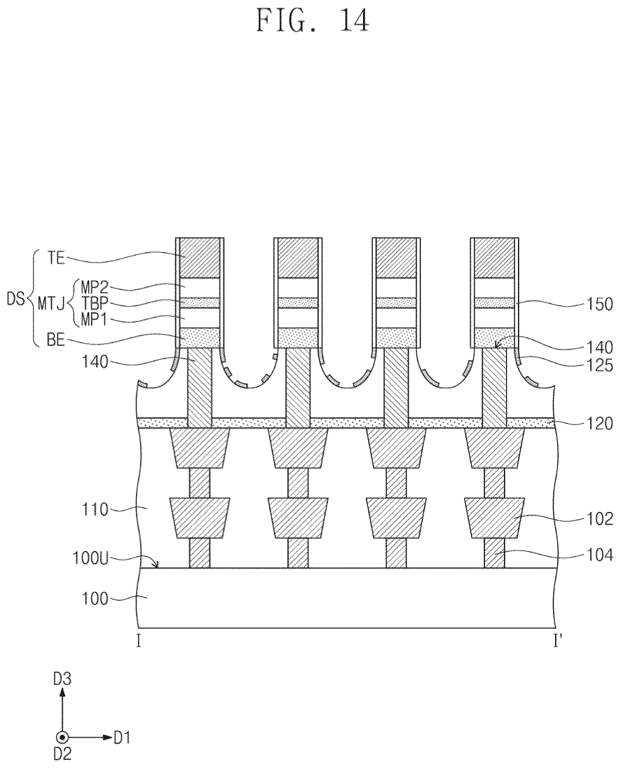

Referring to FIG. 14, dielectric patterns 125 may be formed on the lower dielectric layer 130 and between the data storage patterns DS. The dielectric patterns 125 may be spaced apart from each other along the recessed top surface 130RU of the lower dielectric layer 130. The formation of the dielectric patterns 125 may include oxidizing the preliminary dielectric patterns P125. For example, an ion beam plasma process may be performed to oxidize the preliminary dielectric patterns P125.

In general, an etching process that etches the magnetic tunnel junction layer and the lower electrode layer may form the redeposited material patterns Rd between the data storage patterns DS. The redeposited material patterns Rd may have conductivity, and thus there may occur a short circuit in which the data storage patterns DS are electrically connected to each other. According to the disclosure, the redeposited material patterns Rd may be oxidized to form the dielectric patterns 125 between the data storage patterns DS. This configuration may block a leakage current between the data storage patterns DS and may prevent an electrical short. It may therefore be possible to provide a magnetic memory device with improved electrical properties.

In addition, according to the disclosure, after the first etching process is performed to etch the portion of the preliminary capping pattern layer P150 on the recessed top surface 130RU of the lower dielectric layer 130, no additional etching process may be required to remove the redeposited material patterns Rd. Thus, the lower dielectric layer 130 below the redeposited material patterns Rd may not be etched, and accordingly the lower dielectric layer 130 may be prevented from interface defects thereof. As a result, it may be possible to provide a magnetic memory device with enhanced interface properties and a method of fabricating a magnetic memory device whose process difficulty is improved.

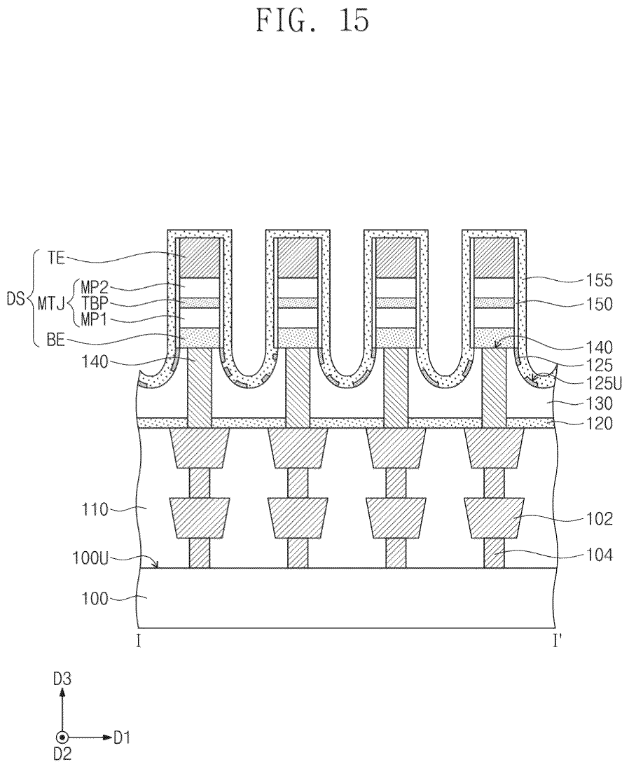

Referring to FIGS. 2 and 15, a capping dielectric layer 155 may be formed on the lower dielectric layer 130. The capping dielectric layer 155 may cover an exposed top surface of the lower dielectric layer 130 and top surfaces 125U of the dielectric patterns 125. Other processes may be identical or similar to those discussed with reference to FIGS. 2 to 11.

According to the disclosure, dielectric patterns may be disposed between data storage patterns. In general, an etching process for forming the data storage patterns may form a redeposited material pattern on a lower dielectric layer. The redeposited material may be disposed between the data storage patterns and may exhibit conductivity. A leakage current may occur through the redeposited material, and a short circuit may appear in which the data storage patterns are connected to each other. In the disclosure, the redeposited material may be oxidized to form a dielectric pattern. Therefore, it may be possible to prevent the occurrence of leakage current between the data storage patterns and to provide a magnetic memory device with improved electrical properties.

The aforementioned description provides some embodiments for explaining the disclosure. Therefore, the disclosure are not limited to the embodiments described above, and it will be understood by one of ordinary skill in the art that variations in form and detail may be made therein without departing from the spirit and essential features of the disclosure.

What is claimed is:

1. A magnetic memory device comprising:
a substrate;
a lower dielectric layer on the substrate;
a plurality of lower electrode contacts in the lower dielectric layer, the plurality of lower electrode contacts being spaced apart from each other in a first direction parallel to a top surface of the substrate;
a plurality of data storage patterns respectively on the plurality of lower electrode contacts, the plurality of data storage patterns being spaced apart from each other in the first direction; and
a plurality of dielectric patterns on the lower dielectric layer between the plurality of data storage patterns,
wherein the plurality of dielectric patterns comprise a metal element that is same or substantially same as that of the plurality of data storage patterns.

2. The magnetic memory device of claim 1, wherein the plurality of dielectric patterns comprise metal oxide.

3. The magnetic memory device of claim 1, wherein a top surface of the lower dielectric layer is recessed inwardly to one of the plurality of dielectric patterns between the plurality of data storage patterns, and
wherein the plurality of dielectric patterns are on the top surface of the lower dielectric layer.

4. The magnetic memory device of claim 3, further comprising a plurality of capping patterns that are spaced apart from each other in the first direction,
wherein the plurality of capping patterns respectively cover a plurality of lateral surfaces of the plurality of data storage patterns.

5. The magnetic memory device of claim 4, further comprising a capping dielectric layer that covers at least one lateral surface of at least one capping pattern in the plurality of capping patterns,
wherein the capping dielectric layer covers at least one top surface of at least one dielectric pattern in the plurality of dielectric patterns.

6. The magnetic memory device of claim 5, wherein a lowermost surface of at least one capping pattern in the plurality of capping patterns is higher than a height of a lowermost surface of the capping dielectric layer.

7. The magnetic memory device of claim 1, wherein a lowermost surface of at least one dielectric pattern in the plurality of dielectric patterns is lower than top surfaces of the plurality of lower electrode contacts.

8. The magnetic memory device of claim 5, wherein a lowermost surface of the capping dielectric layer is lower than top surfaces of the plurality of lower electrode contacts.

9. The magnetic memory device of claim 5, wherein the at least one capping pattern comprises a material that is the same or substantially same as a material of the capping dielectric layer.

10. The magnetic memory device of claim 1, further comprising a wiring structure between the substrate and the lower dielectric layer,
wherein at least one lower electrode contact in the plurality of lower electrode contacts is connected to at least one of uppermost conductive lines in the wiring structure.

11. The magnetic memory device of claim 5, wherein the plurality of dielectric patterns are spaced apart from each other along the top surface of the lower dielectric layer, and
wherein the capping dielectric layer covers the at least one top surface of the at least one dielectric pattern.

12. A magnetic memory device comprising:
a lower dielectric layer on a substrate;
a plurality of data storage patterns that are horizontally spaced apart from each other on the lower dielectric layer;
a plurality of dielectric patterns on the lower dielectric layer between the plurality of data storage patterns; and
a capping dielectric layer that covers at least one lateral surface of at least one data storage pattern in the plurality of data storage patterns,
wherein a top surface of the lower dielectric layer is recessed inwardly to one of the plurality of dielectric patterns between the plurality of data storage patterns,
wherein the capping dielectric layer extends from the at least one lateral surface of the at least one data storage pattern onto the top surface of the lower dielectric layer, and
wherein the plurality of dielectric patterns are between the capping dielectric layer and the top surface of the lower dielectric layer, and include a metal element that is the same or substantially same as that of the plurality of data storage patterns.

13. The magnetic memory device of claim 12, wherein the plurality of dielectric patterns include metal oxide.

14. The magnetic memory device of claim 12, further comprising a plurality of capping patterns between the plurality of data storage patterns and the capping dielectric layer, the plurality of capping patterns respectively covering lateral surfaces of the plurality of data storage patterns,
wherein the capping dielectric layer covers at least one top surface and at least one lateral surface of at least one capping pattern in the plurality of capping patterns.

15. The magnetic memory device of claim 14, wherein a lowermost surface of at least one capping pattern in the plurality of capping patterns is higher than a lowermost surface of the capping dielectric layer.

16. A magnetic memory device comprising:
a lower dielectric layer on a substrate;
a plurality of data storage patterns on the lower dielectric layer and spaced apart from each other in a first direction and a second direction that are parallel to a top surface of the substrate and intersecting each other;
a plurality of lower electrode contacts between the substrate and the plurality of data storage patterns, the plurality of lower electrode contacts being in the lower dielectric layer and respectively connected to the plurality of data storage patterns;
a capping dielectric layer that covers at least one lateral surface of at least one data storage pattern in the plurality of data storage patterns;
a plurality of cell conductive lines that extend in the second direction and are spaced apart from each other in the first direction,
wherein the plurality of cell conductive lines are respectively connected to the plurality of data storage patterns, and
wherein the plurality of data storage patterns are spaced apart from each other in the second direction; and
a plurality of dielectric patterns on the lower dielectric layer and between the plurality of data storage patterns,
wherein the plurality of dielectric patterns include metal oxide, and
wherein the capping dielectric layer covers at least one top surface of at least one dielectric pattern in the plurality of dielectric patterns.

17. The magnetic memory device of claim 16, wherein the plurality of dielectric patterns include a metal element that is same or substantially same as that of the plurality of data storage patterns.

18. The magnetic memory device of claim 16, wherein a top surface of the lower dielectric layer is recessed inwardly to one of the plurality of dielectric patterns between the plurality of data storage patterns, and
wherein the plurality of dielectric patterns are on the top surface of the lower dielectric layer.

19. The magnetic memory device of claim 18, further comprising a plurality of capping patterns between the plurality of data storage patterns and the capping dielectric layer,
wherein the plurality of capping patterns respectively cover lateral surfaces of the plurality of data storage patterns, and
wherein lowermost surfaces of the plurality of capping patterns are lower than lowermost surfaces of the plurality of dielectric patterns.

20. The magnetic memory device of claim 19, wherein the capping dielectric layer covers lateral surfaces of the plurality of capping patterns, extends along the top surface of the lower dielectric layer, and covers the top surface of the plurality of dielectric patterns.
